(19) United States
(12) Patent Application Publication
(10) Pub. No.: US 2025/0191995 A1
(43) Pub. Date: Jun. 12, 2025

(54) THERMAL TRANSFER VIAS AND SEMICONDUCTOR VIA STRUCTURE FOR ENHANCED THERMAL TRANSFER

(71) Applicant: International Business Machines Corporation, Armonk, NY (US)

(72) Inventors: Brent A. ANDERSON, Jericho, VT (US); David WOLPERT, Poughkeepsie, NY (US); Albert M. CHU, Nashua, NH (US); Leon SIGAL, Monsey, NY (US); Lawrence A. CLEVENGER, Saratoga Springs, NY (US); Smitha REDDY, Fishkill, NY (US); Benjamin Neil TROMBLEY, Hopewell Junction, NY (US); Alexander Joel SUESS, Hopewell Junction, NY (US)

(21) Appl. No.: 18/537,385

(22) Filed: Dec. 12, 2023

(51) Int. Cl. H01L 23/367; H01L 23/48; H01L 23/522

(52) U.S. Cl. CPC H01L 23/3677; H01L 23/481; H01L 23/5222

(57) ABSTRACT

Embodiments herein describe thermal transfer vias and via structures of a semiconductor structure, and methods for implementing thermal transfer vias and via structures for enhanced thermal transfer in the semiconductor structure of integrated circuit designs. A disclosed thermal transfer via comprises a conductive material for thermally transferring heat, and a via structure comprises at least one thermal transfer via providing enhanced thermal transfer in the semiconductor structure of an integrated circuit design.

### BACKGROUND

The present invention relates to integrated circuit design, and more specifically, to semiconductor structures for implementing enhanced thermal transfer in an integrated circuit (IC) chip design.

In semiconductor chip designs, providing effective thermal control in a semiconductor structure remains a challenge. Current semiconductor chip designs continue to have increased heat, for example, resulting from increased dielectric layers and smaller device sizes and, which can increase power density and increase heat. New techniques and semiconductor structures are needed to implement enhanced thermal transfer for semiconductor structures, particularly to provide thermal transfer from areas of high heat producing components to target areas and heat sinks of the semiconductor chip designs.

### SUMMARY

Embodiments of the present disclosure are directed to semiconductor via structures, thermal transfer vias, and methods for implementing semiconductor structures for enhanced thermal transfer in a semiconductor structure of integrated circuit designs.

A disclosed non-limiting semiconductor structure comprises a first layer comprising: a thermal dummy transfer via comprising a conductive material for thermally conducting heat that is not electrically active; and an active via that is connected at respective ends to active metal lines.

Another disclosed non-limiting semiconductor structure comprises a first layer comprising: a thermal active transfer via comprising a conductive material for thermally conducting heat is connected at respective ends to active metal lines; and an active via that is connected at respective ends to active metal lines, where a width of the thermal active transfer via is at least two times a width of the active via.

A disclosed non-limiting computer implemented method comprises selecting at least one configuration for at least one thermal transfer via comprising a conductive material for thermally conducting heat in a semiconductor structure; at least one area for placement of a via structure comprising the at least one thermal transfer via in the semiconductor structure; and determining a target via thermal conductive volume for the via structure, based on combined via density rules for semiconductor processing and via density rules for thermal transfer in the semiconductor structure, to provide a target thermal transfer in the semiconductor structure.

### BRIEF DESCRIPTION OF THE DRAWINGS

FIG. 1 is a block diagram of an example computer environment for use in conjunction with one or more disclosed embodiments;

FIG. 2 schematically illustrates example semiconductor via structures of a semiconductor chip design of one or more disclosed embodiments;

FIG. 3A schematically illustrates a configuration of an example thermal transfer via of semiconductor via structures of one or more disclosed embodiments;

FIG. 3B schematically illustrates another configuration of an example thermal transfer via of semiconductor via structures of one or more disclosed embodiments;

FIG. 4A schematically illustrates another configuration of an example thermal transfer via of semiconductor via structures of one or more disclosed embodiments;

FIG. 4B schematically illustrates another configuration of an example thermal transfer via of semiconductor via structures of one or more disclosed embodiments;

FIG. 5 schematically illustrates example configurations of an example thermal transfer via of semiconductor via structure with fill metal lines of one or more disclosed embodiments;

FIG. 6A schematically illustrates an example configuration of an example thermal transfer via of a semiconductor via structure with fill and signal lines of one or more disclosed embodiments;

FIG. 6B schematically illustrates another example configuration of an example thermal transfer via of a semiconductor via structure with fill and signal lines of one or more disclosed embodiments;

FIG. 6C provides a schematic circuit illustration of parasitic capacitance as seen by the signal line of the illustrated configurations of FIGS. 6A and 6B of one or more disclosed embodiments;

FIG. 7 illustrates an example via density pattern of multiple conventional active vias with an example thermal transfer via of one or more disclosed embodiments; and

FIG. 8 is a flow chart of example operations of a method for implementing semiconductor via structures with at least one thermal transfer via of one or more disclosed embodiments in a semiconductor chip design.

### DETAILED DESCRIPTION

The embodiments herein describe enhanced semiconductor via structures comprising enhanced thermal transfer vias and techniques for implementing enhanced thermal transfer in a semiconductor structure of integrated circuit designs or semiconductor chip designs. An enhanced thermal transfer via is formed of a conductive material for thermally conducting heat, and included in a via structure, which is configured to provide enhanced thermal transfer in the semiconductor structure of disclosed embodiments. The enhanced thermal transfer via is a thermal dummy transfer via or a thermal active transfer via. A via structure of the semiconductor structure includes at least one enhanced thermal transfer via. At least one thermal transfer vias is configured to provide a target thermal transfer in a semiconductor structure, providing enhanced thermal performance over conventional via arrangements. The disclosed thermal transfer via enables enhanced thermal transfer within one or more given regions and layers of the semiconductor structure including areas of relatively high-power density and of relatively low metal areas that is not possible with conventional via arrangements.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

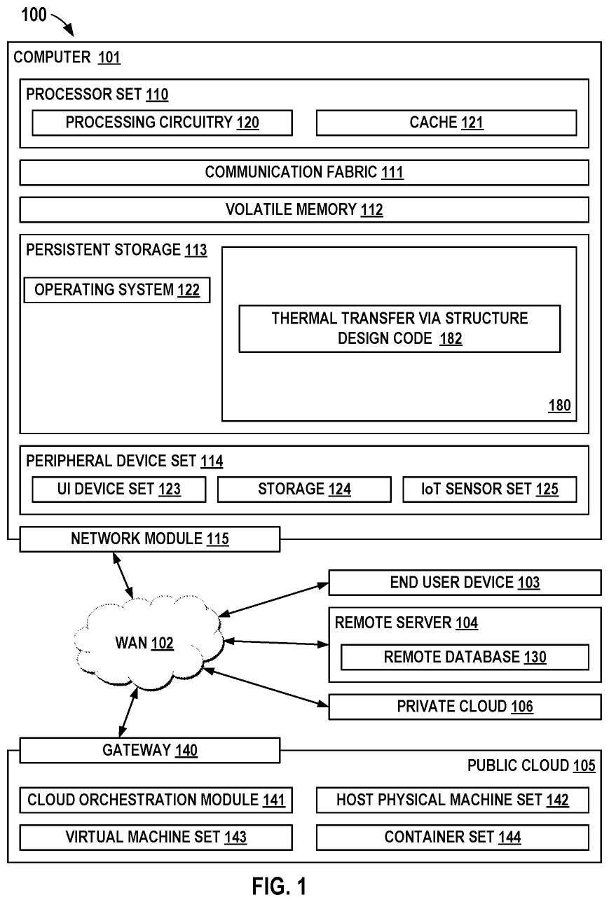

Referring to FIG. 1, a computing environment 100 contains an example of an environment for the execution of at least some of the computer code involved in performing the inventive methods, such as Thermal Transfer Via Design Code 182, at block 180. In addition to block 180, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 180, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 180 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in block 180 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

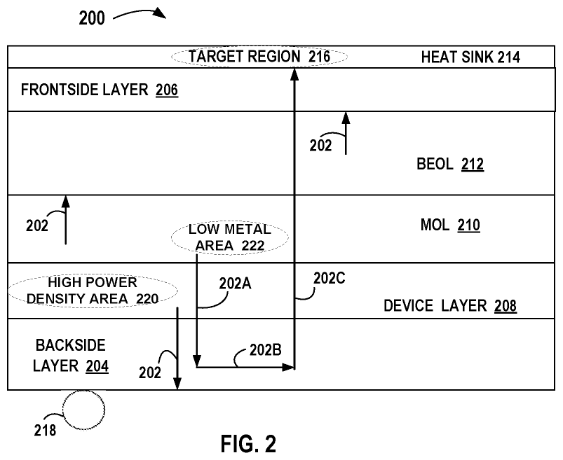

FIG. 2 schematically illustrates an example semiconductor structure 200 including a via structure comprising one or more thermal transfer vias of disclosed embodiments, which provide enhanced thermal transfer in the semiconductor structure 200 of a given integrated circuit design. Multiple thermal transfer paths 202, provided in the semiconductor structure 200 are represented by respective arrows, are provided by a via structure including thermal transfer vias of disclosed embodiments. As shown, the semiconductor structure 200 includes a backside layer 204, a frontside layer 206, a device layer 208, a middle-of-line (MOL) processing region 210, and a backside end-of-line (BEOL) processing region 212. The frontside layer 206 of the semiconductor structure 200 includes a heat sink layer 214 of a thermal target region 216, and the backside layer 204 includes a device layer (a.k.a a controlled collapse chip connection pad or “C4 contact pad”. The illustrated thermal target region 216 of the heat sink layer 214 and the C4 contact pad 218 may be electrically and mechanically connected to various components within the semiconductor structure 200. The semiconductor structure 200 includes one or more high power density areas 220 (one shown) and one or more low metal areas 222 (one shown) within one or more layers of the semiconductor structure. It should be understood that the semiconductor structure 200 shown of FIG. 2 is an illustrative only and a semiconductor structure including the via structure comprising one or more thermal transfer vias of disclosed embodiments, may include other regions, areas, and layers,

Thermal transfer paths 202 provided by the via structure in the semiconductor structure 200 include one or more thermal transfer paths 202 extending between a heat source region (e.g., the thermal transfer paths 202 provided in available space in one or more high power density areas 220 and/or low metal areas 222 of the semiconductor structure) and a thermal target region 216 of the heat sink 214 configured to provide enhanced thermal transfer in the semiconductor structure 200. As shown, the multiple thermal transfer paths 202 in the semiconductor structure 200 include one thermal transfer path 202 extending within the BEOL processing region 212, another transfer path between the device layer 208 and backside layer 204, and another thermal transfer path 202 extending within the MOL processing region 210. As shown, the multiple thermal transfer paths 202 include a vertical downward heat transfer path 202A, a lateral heat transfer path 202B, and a vertical upward heat transfer path 202C. As shown, the thermal transfer paths 202A, 202B, and 202C extend downward from the MOL processing region 210 of the device layer 208 to the backside layer 204, and then extending in a lateral direction in the backside layer 204, and extending in vertical upward direction through the BEOL processing region 212 of the device layer 208 and the frontside layer 206 to the target region 216 of the heat sink 214.

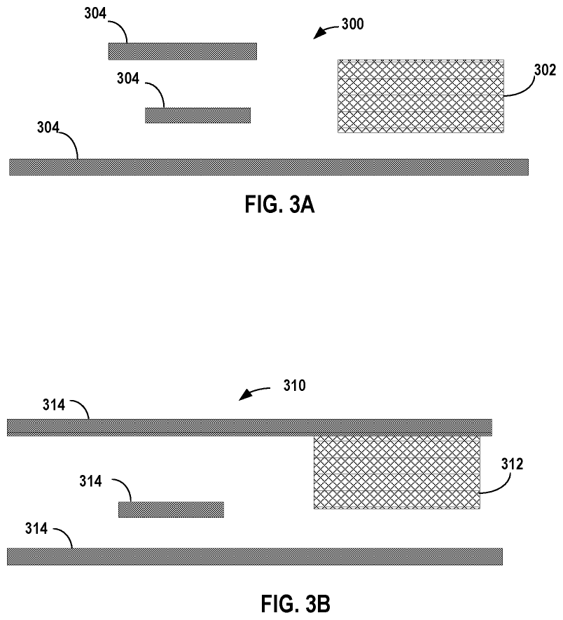

Example thermal transfer vias of one or more embodiments are illustrated and described with respect to FIGS. 3A, 3B, 4A, 4B, 5, 6A, 6B, and 7. The thermal transfer vias of disclosed embodiments are formed of a conductive material for thermally conducting heat, which may be a thermally and electrically conductive material, such as used for forming standard active vias and signal and metal fill lines of the semiconductor structure 200. The thermal dummy transfer via is placed in an available location of a selected area of the semiconductor structure, the selected area comprises one of an area of relatively low metal, or an area of relatively high-power density from heat producing components. For example, the one or more thermal transfer vias within the semiconductor via structure may be formed of a selected metal material, such as a copper (Cu). For example, the one or more thermal transfer vias within the semiconductor via structure may be formed using one of damascene via formation and subtractive via formation. The one or more thermal transfer vias within the semiconductor via structure may have various shapes, sizes and locations within the semiconductor structure 200 for providing target via thermal conductive capacities to achieve a target thermal transfer in the semiconductor structure. The one or more thermal transfer vias are located within one or more of regions including a middle-of-line (MOL) region, a backside end-of-line (BEOL) region, a through-device region, or a backside region.

FIG. 3A schematically illustrates a configuration 300 of an example thermal transfer via 302 of one or more disclosed embodiments. In one embodiment, the thermal transfer via 302 is a thermal dummy transfer via that is not electrically active, and the dummy via 302 is isolated from active lines (not shown in FIG. 3A).

FIG. 3B schematically illustrates another configuration 310 of an example thermal transfer via 312 of semiconductor via structures of one or more disclosed embodiments. In one embodiment, the thermal transfer via 312 is a thermal dummy transfer via that is not electrically active but is located on an active line 314, and spaced apart from other active lines 314, as shown. In accordance with an embodiment, a defined minimum distance is provided from the thermal transfer via 312 to other active lines 314, and to one or more active components in the semiconductor structure to optimize yield, (e.g., avoid shorting) and avoid added parasitic capacitance.

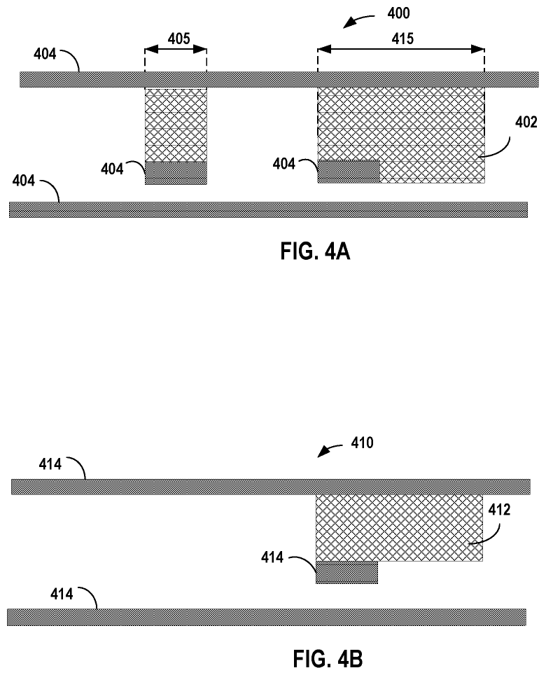

FIG. 4A schematically illustrates another configuration 400 of an example thermal transfer via 402 of semiconductor via structures of one or more disclosed embodiments. The thermal transfer via 402 is an enlarged thermal active transfer via, which extends between a pair of active lines 404 and extends above and beyond a line edge of one of the active lines 404, as shown. A width (e.g., size) of an illustrated standard (normal) active via at the same level in the semiconductor structure 200 is indicated by an arrow 405. A size of the enlarged thermal active transfer via 402, indicated by arrow 415, is at least two times (or in a range between 2 to 10 times) greater than the standard active via size.

FIG. 4B schematically illustrates another configuration 410 of an example thermal active transfer via 412 of semiconductor via structures of one or more disclosed embodiments. The thermal transfer via 412 is an enlarged active via, that is connected to a first active signal line 414 and a second active signal line 414 in the semiconductor structure and extends beyond and below a line edge of one of the active lines 404, as shown.

As shown in FIGS. 3A, 3B, 4A and 4B, the thermal dummy transfer vias 302 and 312, and the thermal active transfer vias 402 and 412 have a size that is greater than two times the standard size of one of the active lines 404, such as illustrated in FIG. 4A. The size of the thermal dummy transfer vias 302 and 312, and the thermal active transfer vias 402 and 412 is based on a target thermal transfer in the semiconductor structure 200. The target thermal transfer provided by the thermal transfer vias 302, 312, 402, and 412 advantageously can compensate for increased heat produced in current semiconductor structures 200, for example, resulting from increased dielectric layers and smaller device sizes.

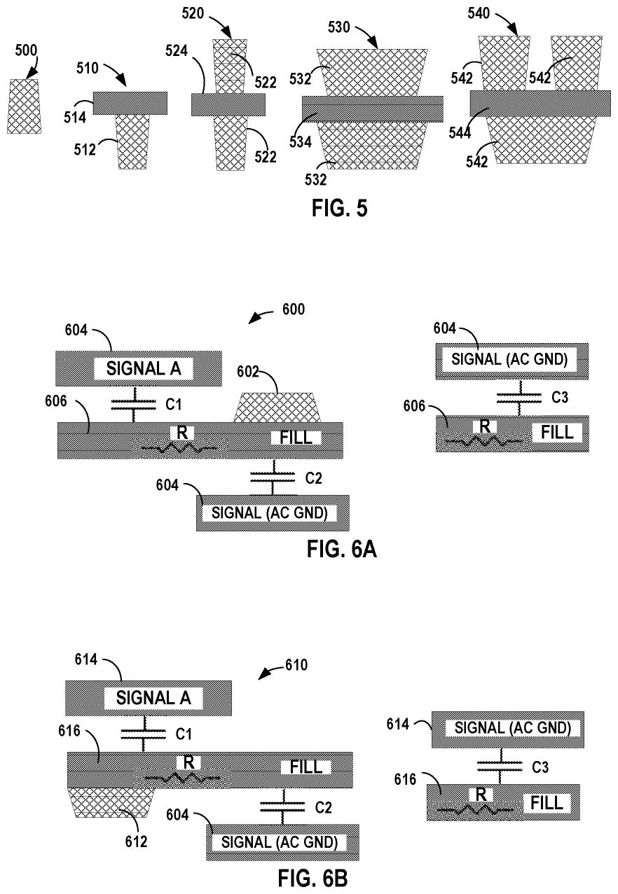

FIG. 5 schematically illustrates multiple example configurations of thermal transfer vias of one or more disclosed embodiments in areas of metal fill including dummy fill lines. For example, areas of metal fill are provided in conventional semiconductor processes of a given semiconductor structure 200. In this example, an illustrated thermal transfer via 500 is a dummy via that is not electrically active located in an area of metal fill. Another via configuration 510 includes a thermal transfer via 512, which is a dummy via that is not electrically active located below a dummy fill line 514. Another configuration 520 includes a pair of thermal transfer vias 522, the thermal transfer vias 522 are dummy vias that are not electrically active and located above and below of a dummy fill line 514. Another configuration 530 includes a pair of enlarged thermal transfer vias 532, the enlarged thermal transfer vias 532 are dummy vias that are not electrically active and located above and below of a dummy fill line 534. Another configuration 540 includes three enlarged thermal transfer via 542, the enlarged thermal transfer vias 542 are dummy vias that are not electrically active, and two of the enlarged thermal transfer vias 542 are located above a dummy fill line 544 and the other enlarged thermal transfer vias 542 are located below the dummy fill line 544.

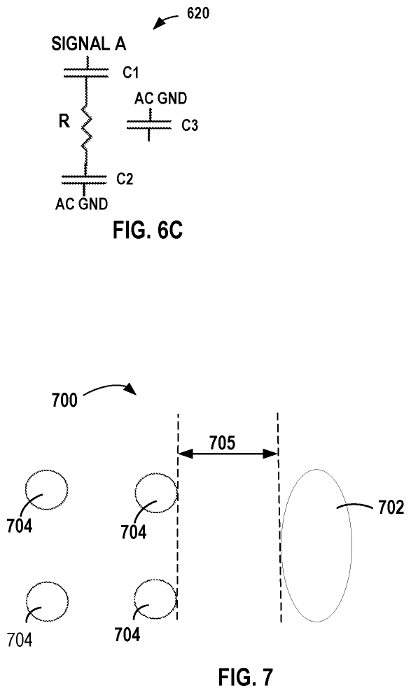

FIG. 6A schematically illustrates a thermal transfer via configuration 600 of an example thermal transfer via 602 in areas of metal fill of one or more disclosed embodiments. As shown, the thermal transfer via 602 is a dummy via that are not electrically active, spaced apart from adjacent active signal lines 604, Signal A and Signal AC ground. The thermal dummy transfer via 602 is located above a first dummy fill line 606 and spaced apart from an adjacent second dummy fill line 606. In the thermal transfer via configuration 600, the dummy thermal transfer via 602 is spaced apart from the active signal lines 604 and the other dummy fill line 606 to improve yield and minimizes parasitic capacitance. A subtractive via formation can be used to form the dummy thermal dummy transfer via 602.

FIG. 6B schematically illustrates another similar configuration 610 of an example thermal transfer via 612 in areas of metal fill of one or more disclosed embodiments. As shown, the thermal transfer via 612 is a dummy via that are not electrically active, spaced apart from adjacent active signal lines 614, Signal A and Signal AC ground. The thermal dummy transfer via 612 is located below a first dummy fill line 616 and spaced apart from an adjacent second dummy fill line 616. In the thermal transfer via configuration 610, the dummy thermal transfer via 612 is spaced apart from the active signal lines 614 and the other dummy fill line 616 to improve yield and minimize parasitic capacitance. A damascene via formation can be used to form the thermal dummy transfer via 612.

As shown in FIG. 6A and FIG. 6B, parasitic capacitance C1 exists between the active signal line 614, Signal A and the first dummy fill line 616, parasitic capacitance C2 exists between the first dummy fill line 616, and active signal line 614, Signal (AC ground), and parasitic capacitance C3 exists between the second dummy fill line 616 and another active signal line 614, Signal (AC ground). As shown, the respective first dummy fill line 616 and the adjacent second dummy fill line 616 include a resistance value R. In both the thermal transfer via configuration 600 in FIG. 6A and the thermal transfer via configuration 610 in FIG. 6B, the dummy thermal transfer via 602, 612 are spaced apart from the active signal lines 614 Signal A and AC ground and the other dummy fill line 616 to improve yield (e.g., avoid shorting) and minimize effects of the parasitic capacitance. FIG. 6C provides a schematic illustration of a parasitic resistance capacitance model 620 as seen by the active line 604, Signal A, in both the thermal transfer via configuration 600 of the dummy thermal transfer via 602 and the thermal transfer via configuration 610 of the dummy thermal transfer via 612. As shown in FIG. 6C, the parasitic capacitance C3 remains separate from parasitic capacitance C1 and C2 with fill resistance value R of the respective fill lines 616, and advantageously does not add to parasitic effect of the fill resistance value R with parasitic capacitance C1 and C2 on the active signal line 614, Signal A.

FIG. 7 illustrates a top view of an example via density pattern 700 of one or more disclosed embodiments. As shown, the via density pattern 700 includes an example thermal transfer via 702 with multiple standard active vias 704 of one or more disclosed embodiments. The thermal transfer via 702 is one of a thermal dummy transfer via or a thermal active transfer via of disclosed embodiments. As shown, the thermal transfer via 702 has an oval shape and is substantially larger than the standard active vias 704. The thermal transfer via 702 is an enlarged via, having a selected size, based on thermal transfer capability, for example, which is 2 to 10 times greater than the standard active vias 704. In a disclosed embodiment, the via size, location, and via configuration (e.g., active verses dummy via configuration) of the thermal transfer via 702 is determined based on via density rules for semiconductor processing combined new via density rules for thermal transfer of disclosed embodiments. A predefined minimum spacing between the thermal transfer via 702 and the active vias 704 indicated by arrow 705 (e.g., other active nets or signal lines) enables improved capacitance and yield, (e.g., avoiding added parasitic capacitance, avoiding electrical shorting, and the like).

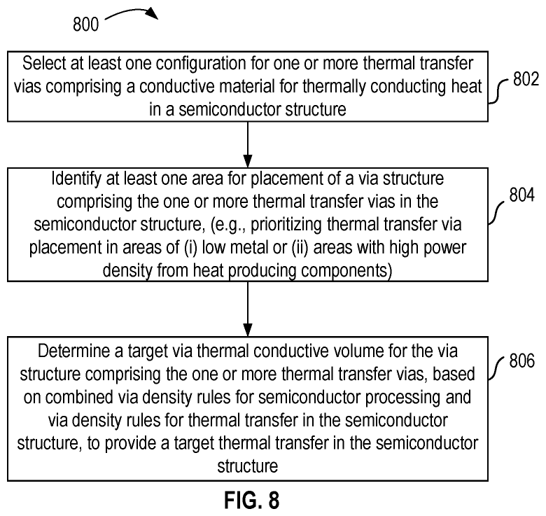

FIG. 8 is a flow chart of example operations of a method 800 for implementing semiconductor via structures with at least one thermal transfer via of one or more disclosed embodiments in a semiconductor structure 200. The method 800 can be implemented by the computer 101 of the cloud environment 100 of FIG. 1 with the Thermal Transfer Via Design Code 182.

At block 802, a computing system selects at least one configuration for one or more thermal transfer vias comprising conductive material for thermally conducting heat in a semiconductor structure. In one embodiment, a selected configuration of thermal transfer vias may be provided to optimize via size, location, number of enlarged active or dummy vias, to optimize yield and minimize parasitic capacitance of the thermal transfer vias.

At block 804, the computing system identifies areas for placement of the one or more thermal transfer vias of the via structure in the semiconductor structure, for example, prioritizing thermal transfer via placement in areas of relatively low metal and other areas with relatively high-power density from circuit components.

At block 806, the computing system determines a via target via thermal conductive volume of the via structure including the one or more thermal transfer vias, based on combined via density rules for semiconductor processing and via density rules for thermal transfer in the semiconductor structure, to provide thermal transfer in the semiconductor structure. The computing system determines the target via thermal conductive volume to provide enhanced thermal transfer in the semiconductor structure, where the via density rules for thermal transfer may include a number of the standard active vias and a number of the thermal transfer vias and/or top-down combined area of the standard active vias and the thermal transfer vias in one or more areas of the semiconductor structure. In one embodiment, the computing system determines the target via thermal conductive volume, performing analysis, using the combined via density rules, to optimize for capacitance, yield, and targeted thermal transfer.

While the foregoing is directed to embodiments of the present invention, other and further embodiments of the invention may be devised without departing from the basic scope thereof, and the scope thereof is determined by the claims that follow.

What is claimed is:

1. A semiconductor structure, comprising:
a first layer comprising:
a thermal dummy transfer via comprising a conductive material configured for thermally conducting heat that is not electrically active; and
an active via that is connected at respective ends to active metal lines.

2. The semiconductor structure of claim 1, wherein the thermal dummy transfer via is located on one of the active metal lines.

3. The semiconductor structure of claim 1, wherein the first layer further comprises a metal fill line, and wherein the thermal dummy transfer via is located on the metal fill line.

4. The semiconductor structure of claim 1, wherein the thermal dummy transfer via is spaced apart from the active lines by a predefined distance to optimize yield and parasitic capacitance resulting from the dummy thermal transfer via.

5. The semiconductor structure of claim 1, wherein the first layer further comprises a plurality of metal fill lines, and wherein the thermal dummy transfer via is located on one metal fill line spaced apart from other metal fill lines by a predefined distance to optimize yield and parasitic capacitance resulting from the dummy thermal transfer via.

6. The semiconductor structure of claim 1, wherein the thermal dummy transfer via has a selected size based on a target thermal transfer in the semiconductor structure.

7. The semiconductor structure of claim 1, further comprises a selected number of thermal dummy transfer vias based on a target thermal transfer in the semiconductor structure.

8. The semiconductor structure of claim 1, wherein the thermal dummy transfer via has a selected shape based on a target thermal transfer in the semiconductor structure.

9. The semiconductor structure of claim 1, wherein the thermal dummy transfer via has a size greater than two times a size of the active via at a same level in the semiconductor structure.

10. The semiconductor structure of claim 1, wherein the thermal dummy transfer via is formed using one of damascene via formation, or subtractive via formation.

11. The semiconductor structure of claim 1, wherein the thermal dummy transfer via is located in at least one of a middle-of-line (MOL) processing region, a backside end-of-line (BEOL) processing region, a through device region, or a backside layer of the semiconductor structure.

12. The semiconductor structure of claim 1, wherein the semiconductor structure further comprises a device layer, a backside layer, and a frontside layer and one or more of the thermal dummy transfer vias, and wherein one or more thermal dummy transfer vias provide a vertical thermal transfer path from the device layer to the backside layer, a lateral thermal transfer path in the backside layer, and a vertical thermal transfer path from the backside layer through the device layer to the frontside layer.

13. The semiconductor structure of claim 1, wherein the thermal dummy transfer via is placed in an available location of a selected area of the semiconductor structure, the selected area comprises one of an area of relatively low metal, or an area of relatively high power density from heat producing components.

14. A semiconductor structure, comprising:
a first layer comprising:
a thermal active transfer via comprising a conductive material configured for thermally conducting heat is connected at respective ends to active metal lines; and
an active via that is connected at its respective ends to the active metal lines, wherein a width of the thermal active transfer via is at least two times a width of the active via.

15. The semiconductor structure of claim 14, wherein the thermal active transfer via is formed using one of damascene via formation or subtractive via formation.

16. The semiconductor structure of claim 14, wherein the thermal active transfer via has a selected size based on a target thermal transfer in the semiconductor structure, and the thermal active transfer via extends beyond a line edge of one of the connected active metal lines.

17. The semiconductor structure of claim 14, wherein the thermal active transfer via is placed in an available location of a selected area of the semiconductor structure, the selected area comprises one of an area of relatively low metal, or an area of relatively high-power density from heat producing components.

18. The semiconductor structure of claim 14, wherein the thermal active transfer via is located in at least one of a middle-of-line (MOL) processing region, a backside end-of-line (BEOL) processing region, a through device region, or a backside layer of the semiconductor structure.

19. A computer implemented method, comprising:
selecting at least one configuration for one or more thermal transfer vias comprising a conductive material for thermally conducting heat in a semiconductor structure;
identifying at least one area for placement of a via structure comprising the at least one thermal transfer via in the semiconductor structure; and
determining a target via thermal conductive volume for the via structure, based on combined via density rules for semiconductor processing and via density rules for thermal transfer in the semiconductor structure, to provide a target thermal transfer in the semiconductor structure.

20. The computer implemented method of claim 19, wherein identifying at least one area for the placement further comprises prioritizing the placement of the via structure in at least one of (i) areas of relatively low metal, or (ii) areas of relatively high-power density from heat producing components in the semiconductor structure.
